(19) United States
(12) Patent Application Publication
(10) Pub. No.: US 2025/0216441 A1
(43) Pub. Date: Jul. 3, 2025

(54) CLOCKLESS AND CALIBRATION-LESS DIFFERENTIAL AGING MONITOR

(71) Applicant: Intel Corporation, Santa Clara, CA (US)

(72) Inventors: Minki CHO, Portland, OR (US); Balkaran GILL, Cornelius, OR (US)

(21) Appl. No.: 18/401,101

(22) Filed: Dec. 29, 2023

(51) Int. Cl. G01R 31/28

(52) U.S. Cl. CPC G01R 31/282

(57) ABSTRACT

An aging detection circuit includes a sensor circuit and a reference circuit. The sensor circuit runs constantly with the operation of the device to be monitored. The sensor circuit can generate a sensor count. The reference circuit is turned off unless enabled for measurement of the device to be monitored. The reference circuit can generate a reference count. The aging detection circuit can include circuitry to determine the aging of the device to be monitored based on a difference between the sensor counter and the reference counter.

### TECHNICAL FIELD

Descriptions are generally related to semiconductor circuits, and more particular descriptions are related to circuit sensors.

### BACKGROUND OF THE INVENTION

With increases in performance in advanced microelectronics technologies, reliability plays a critical role in the power and performance management of high-performance devices, such as microprocessors and IoT (internet of things) devices. One feature monitored for reliability is circuit aging attributes. The system can monitor aging to gather important telemetry information. Aging monitoring has been performed with sensor structures such as ring oscillator circuits, TRCs (tunable replica circuits) using TDC (tunable delay counters), and analog sensors.

The aging monitor circuits are generally single-end sensors, vulnerable to process, temperature, and voltage noise. The aging monitor circuits typically require significant calibration effort and critical signal control such as clock and calibration start and stop signaling. To generate and propagate such signals, the system requires additional area/circuitry, which significantly increases the difficulty of on-product adaptation.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system with aging monitoring

FIG. 2 is a circuit diagram of an example of a clock-less and calibration-less aging monitor.

FIG. 3 is a representation of an example of timing diagram.

FIG. 4 is a representation of an example of a comparison between the reference circuit and the sensor circuit for a non-aged circuit.

FIG. 5 is a representation of an example of a comparison between the reference circuit and the sensor circuit for an aged circuit.

FIG. 6 is a representation of an example of a comparison between the reference circuit and the sensor circuit for temperature changes.

FIG. 7 is a representation of an example of a comparison between the reference circuit and the sensor circuit for voltage supply changes.

FIG. 8 is a circuit diagram of an example of a tunable replica circuit.

FIG. 9 is a circuit diagram of an example of a clock-less and calibration-less aging monitor with frequency measurement.

FIG. 10 is a flow diagram of a process for aging detection.

FIG. 11 is a block diagram of an example of a computing system in which aging detection can be implemented.

FIG. 12 is a block diagram of an example of a mobile device in which aging detection can be implemented.

FIG. 13 is a block diagram of an example of an SOC in which aging detection can be implemented.

Descriptions of certain details and implementations follow, including non-limiting descriptions of the figures, which may depict some or all examples, and well as other potential implementations.

### DETAILED DESCRIPTION OF THE INVENTION

As described herein, an aging detection circuit includes a sensor circuit and a reference circuit. The aging circuit does not require a system clock to operate. The aging circuit operates independently of calibration to the system operation. The sensor circuit runs constantly with the operation of the device to be monitored. The sensor circuit can generate a sensor count. The reference circuit is turned off unless enabled for measurement of the device to be monitored. The reference circuit can generate a reference count. The aging detection circuit can include circuitry to determine the aging of the device to be monitored based on a difference between the sensor counter and the reference counter.

The aging detector described herein can improve the reliability in the power and performance management of high-performance system components, such as microprocessors, memory devices, system peripheral components, IoT (internet of things) devices, or other circuits. The aging monitor can be implemented out of different types of circuits. Instead of implementing the aging circuitry with a single-ended sensor, the aging sensor can be a differential sensor circuit. The differential circuitry can reduce the vulnerability to process and temperature variation, and to voltage noise and variation. As described herein, the aging detectors are sensors that do not need calibration or clock. The lack of need for clock and calibration can reduce the circuit area for the aging circuitry compared to other types of aging sensors.

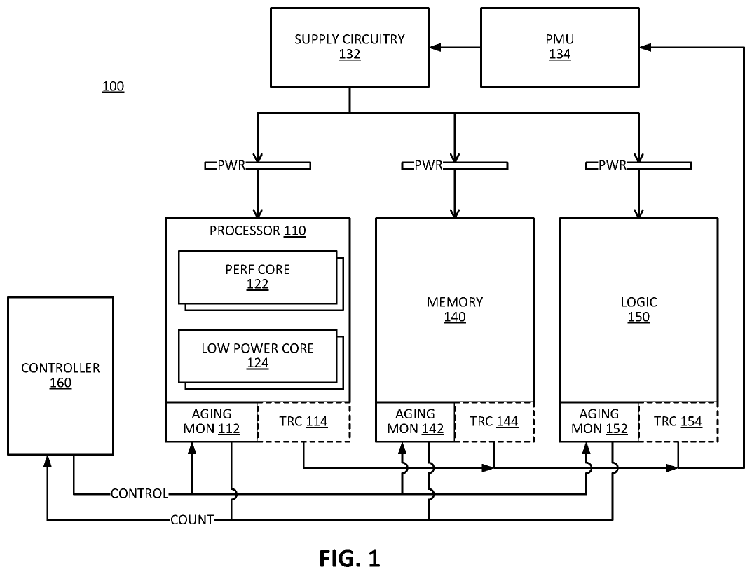

FIG. 1 is a block diagram of an example of a system with aging monitoring. System 100 represents any of a variety of types of systems that can perform aging monitoring to improve system performance. Not all systems will have all components illustrated in system 100. Some system implementations will have different or alternative components to what is illustrated in system 100.

System 100 includes processor 110, which represents a computing device for system 100. Processor 110 can be a single core or a multicore processor. In an implementation where processor 110 is a multicore processor, in one example, processor 110 includes performance (PERF) cores 122 and low power cores (124).

Performance cores 122 refer to cores that perform at higher power and higher performance. Low power cores 124 refer to cores that perform at lower power and do not necessarily require the same level of precision as the high performance cores. In one example, system 100 includes aging monitor (MON) 112 to monitor the aging of processor 110. Aging monitor 112 can monitor the aging of processor 110.

Monitoring the aging of a component can refer to determining if the component has experienced a change in voltage or frequency of operation since the system first started operation. Monitoring can be based on the reference of the differential circuit that is only run when performing an aging check. By running the reference circuit only to perform aging monitoring, the reference circuit is not subject to the same aging as the other circuitry that is always on. Rather, the reference circuit is off most of the time, which means its performance will not degrade or will degrade to a lesser degree than circuitry that runs constantly or nearly constantly when the system is operational.

Aging monitor 112 represents an aging monitor for a processor. In one example, each core of processor 110 can have its own aging monitor 112. Thus, aging monitor 112 does not necessarily represent a singular component. In one example, aging monitor 112 only checks the aging of performance cores 122. For example, performance cores 122 can be implemented with aging monitors, and low power cores 124 can be implemented without aging monitors.

In one example, system 100 includes aging monitor 142 to monitor aging for memory 140. Thus, the aging detection circuit can be a memory aging detection circuit. Memory 140 represents a memory component that operates at high performance. For example, memory 140 can represent a cache memory or other memory level close to processor 110. In one example, memory 140 represents memory implemented on processor 110. In one example, memory 140 represents memory on an SOC (system on a chip) of processor 110.

In one example, system 100 includes aging monitor 152 for logic 150. Logic 150 represents chipset components or other logic circuitry in system 100. Logic 150 can be or include peripheral chipset circuits. Thus, in one example, the aging detection circuit can be an aging detection circuit for a peripheral chipset. In one example, one or more components of logic 150 can be interconnect or management circuits of an SOC of processor 110. Aging monitor 152 can perform aging monitoring for one or more logic components.

Aging monitor 112, aging monitor 142, and aging monitor 152 represent clockless, calibration-less aging monitors. In one example, system 100 includes multiples of any or all of the aging monitors. The multiple components can enable separate monitoring of any component desired to be monitored for aging. Thus, system 100 can include an aging detection circuit as a high-performance circuit aging detection circuit.

A clockless monitor refers to a monitor that does not need the system clock for operation. A calibration-less monitor refers to a monitor that does not require a calibration process to match its operation with the operation of the circuit to be monitored. The monitors described herein can achieve clockless and calibration-less operation through differential measurement between the reference circuit that is turned on for measurement mode and the sensor circuit that runs as often as the component to be measured executes.

Supply circuitry 132 represents voltage regulator circuitry or other circuits to supply power to the components of system 100. Not all components will necessarily have the same power needs. In one example, system 100 includes more than one different supply circuit. Supply circuitry 132 represents the circuitry to provide the power needed for each component subsystem.

PMU (power management unit) 134 represents a power management component for system 100. PMU 134 can monitor the power supplied from supply circuitry 132, including the power supply needs of the different components. In one example, based on the management by PMU 134, supply circuitry 132 can provide power (PWR) to each component. The PWR can represent power adjusted for voltage or frequency needs, to the extent each component has a separate regulator to provide the adjusted power.

In one example, system 100 optionally includes TRC (tunable replica circuit) 114. TRC 114 represents a circuit to provide information to PMU 134 to adjust operation for changes in voltage, changes in frequency, or both. In one example, aging monitor 112 can directly provide aging information to a PMU.

In one example, system 100 includes TRC 144 to provide tunable information to adjust operation in response to the aging. In one example, system 100 includes TRC 154 to provide tunable information to adjust operation in response to the aging. For example, if an aging circuit detects a change in frequency of a high performance component, in one example, the system can change a frequency parameter to optimize for the change in frequency. Similarly, if an aging circuit detects a change in voltage of a component, the system can adjust a voltage parameter to improve component operation.

In one example, the aging monitor circuits are based on ring oscillators, which enables a simple and straightforward way to analyze the impact of aging. In one example, the system has a measurement mode for the reference circuit, such as a reference oscillator, in which the reference circuit is enabled to take a measurement of the circuitry to be monitored. In one example, the aging monitoring enables adaptive techniques, where the system can apply adaptive voltage scaling or adaptive frequency scaling based on aging behavior.

In one example, the monitors described herein monitor their respective components with a preselected timer, which is much less expensive and has higher tolerance to supply noise and temperature. In one example, the monitors described can eliminate the need to save aging status over time, which reduces complexity and eliminates the need for a nonvolatile memory. In one example, the implementation of the aging monitors described herein is limited to normal CMOS (complementary metal-oxide semiconductor) devices.

Controller 160 represents one or more controllers to manage the operation of the aging monitors. In one example, controller 160 is part of PMU 134. In one example, controller 160 part of an SOC controller. In one example, controller 160 is part of peripheral circuitry. Controller 160 can send control signals to the aging monitors to trigger this operation. The aging monitors provide count information, or comparison of count information, back to controller 160, which can then determine whether to perform actions in system 100 based on the aging of the components.

For simplicity, system 100 illustrates a control signal from controller 160 to all the aging monitors, and a single count signal back from all aging monitors to controller 160. In one example, each aging circuit can be separately controlled by controller 160. Thus, controller 160 could be represented with separate lines to each separate aging monitor.

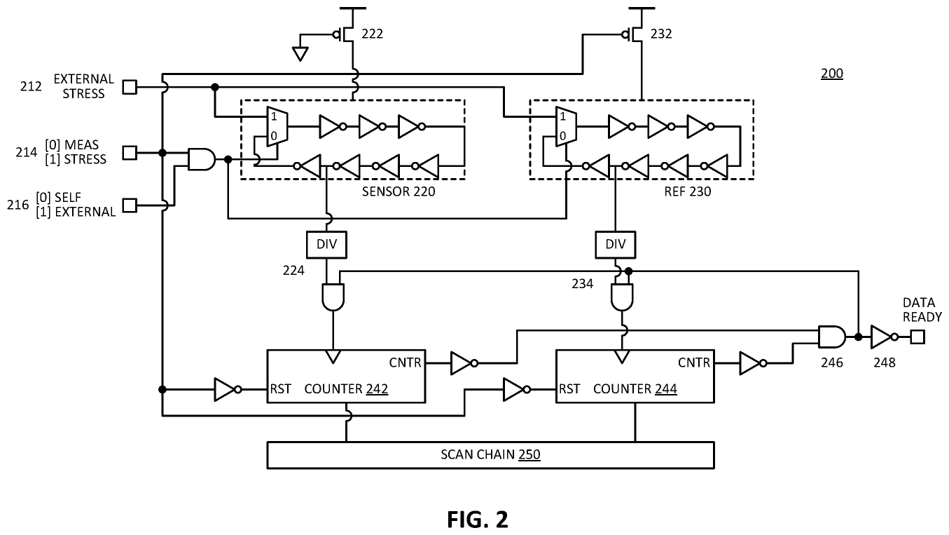

FIG. 2 is a circuit diagram of an example of a clock-less and calibration-less aging monitor. System 200 represents an aging detection circuit in accordance with an example of an aging monitor of system 100. System 200 can be implemented as a monitoring circuit for any component that is to be monitored for aging. Thus, system 200 represents circuitry that can be incorporated into a larger system. The larger system can have multiple instances of system 200.

System 200 represents a clockless and calibration-less aging monitor. As illustrated, system 200 includes two ROs (ring oscillators), each with its own power gate. The separate power gates for the separate ROs enable system 200 to have a reference RO with a power gate that is selectively enabled to allow for selective measurement operation, and a power gate that is always on for a sensor RO.

While system 200 specifically illustrates ring oscillators, in one example, the sensor circuit and the reference circuit can be implemented with different circuits that can generate a differential signal for comparison. System 200 illustrates two counters, one for each RO, with simple logic to interface the counters with the sensing circuitry.

In one example, system 200 includes sensor 220, which represents the sensor portion of the aging monitor. Sensor 220 is power gated by device 222, which is illustrated to be tied to an always-on position. Device 222 can be referred to as a power gating circuit that is hard coded to an enabled state in which power is provided to the RO circuit. Hard coding the power gate to an enabled state ensures sensor 220 is constantly enabled to operate when the system is operational. Thus, when the larger system is operational, sensor 220 will be operational.

In one example, system 200 includes reference (REF) 230, which represents the reference portion of the aging monitor. Reference 230 is power gated by device 232, which is controlled by a control signal. Device 232 can be referred to as a power gating circuit that is selectively enabled to provide power to the RO circuit. In one example, a controller (not specifically illustrated) of the larger system generates the control signal to trigger aging measurement.

System 200 keeps reference 230 fresh during the lifetime of the product by applying power gating through device 232, meaning reference RO power is turned off when not in use for measurement, which means the circuit will not age at the same rate as the operational circuitry. The measurement can be controlled during a measurement mode. In one example, a control algorithm selectively writes a configuration register to start and stop aging measurement. In one example, the control algorithm generates a control signal from an I/O (input/output) circuit to control the power gate.

In one example, sensor 220 feeds an output signal to divider 224. In one example, reference 230 feeds an output signal to divider 234. The dividers can divide the RO frequency before feeding counters. In one example, the output of divider 224 is ANDed with a feedback signal to feed into counter 242. Likewise, in one example, output of divider 234 is ANDed with the feedback signal to feed into counter 244.

Counter 242 and counter 244 can be N-bit counters. To ensure that the measurement is made based on useful measurements, counter 242 and counter 244 can include reset (RST) inputs triggered by the measurement mode control signal. Thus, when the system begins measurement mode, the counters are reset and will count in parallel from the initial count.

Counter 242 can be referred to as a sensor counter, since it counts the signal from the sensor circuit, which can be referred to as a sensor count. Counter 244 can be referred to as a reference counter, since it counts the signal from the reference circuit, which can be referred to as a reference count. In one example, the counter (CNTR) outputs of counter 242 and counter 244 can be ANDed with device 246 and fed back into the signal with the respective dividers. The counter output can be a pre-selected count value for each counter.

Thus, in one example, counter 242 can be configured to stop counting when it reaches a count value in the sensor DUT (device under test). In one example, counter 244 will stop counting at a pre-selected counter value in the reference DUT. By stopping the counting, system 200 can hold the count values without overflow. The output at device 248 can provide a data ready signal to the external controller that makes use of the aging monitoring data.

Counter 242 and counter 244 can output their counts to scan chain 250, which can couple to external control circuitry (not illustrated) to perform operations in response to the count output. In one example, scan chain 250 includes comparator circuitry to compare the count from the sensor portion with the count from the reference portion to determine how the operational circuitry is aging. In one example, scan chain 250 is connected to the counter enable.

System 200 represents multiple control signal inputs as examples. Other control signal inputs can be used. Signal 212 represents an externa stress signal, which can trigger the ROs to run at the system clock frequency. Thus, system 200 represents an aging monitor that can run without a system clock signal, but can optionally run the circuits at the clock frequency. System 200 does not require complicated calibration in the product. In one example, sensor 220 and reference 230 are ROs that can run in self-oscillation mode or can also be stressed at the clock frequency.

Signal 214 represents a measurement mode signal. In one example, when the signal is low [0], it is can trigger measurement mode, and when the signal is high [1], it can switch to a stress mode. Thus, in one example, system 200 can be dynamically controlled by an external controller to switch between stress mode and measurement mode. The stress mode can enable sensor 220 to age at the same rate as the operational circuitry. The measurement signal can be a step signal that does not require high precision and timing.

In addition to the external stress signal, in one example, system 200 provides signal 216, which can represent an enable signal for selecting the external stress signal or using the internal frequency. Signal 216 can trigger the internal frequency as the default with low [0] being a Self signal, and high [1] being an External selection.

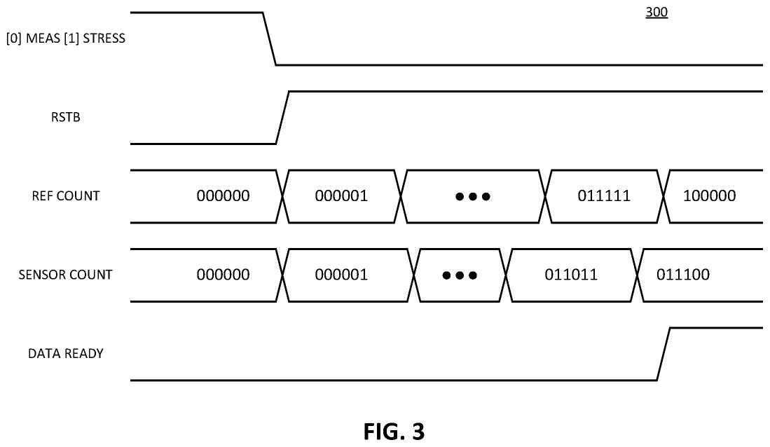

FIG. 3 is a representation of an example of timing diagram. Diagram 300 represents signals that can be in accordance with an example of system 200. The [0] Meas (measurement) and [1] Stress signal represents a measurement mode signal. As illustrated the signal can trigger measurement mode at logic low. Thus, the controller can de-assert the signal to trigger the measurement mode, and assert it to trigger a stress mode. RSTB (reset bit) represents a reset signal for the counters. In response to triggering the measurement mode, the counter can reset to an initial value.

REF (reference) count represents a count for a reference circuit and sensor count represents a count for a sensor circuit. The reference portion ages slower than the sensor portion. Diagram 300 illustrates that the reference count may be faster than the sensor count under aging or stress conditions on the device. Thus, the counting of the reference count is illustrated as reaching a threshold count before the sensor count.

In response to reaching the threshold count, the aging circuit can trigger the data ready signal. Once the data ready signal is triggered, the controller can read the counts. In one example, the aging circuit generates a comparison of the counts, and the controller can read the comparison information. Whether it receives the raw counts or a comparison count, the controller can ensure there is a comparison of the counts, and can determine how the circuits have aged based on the count comparison.

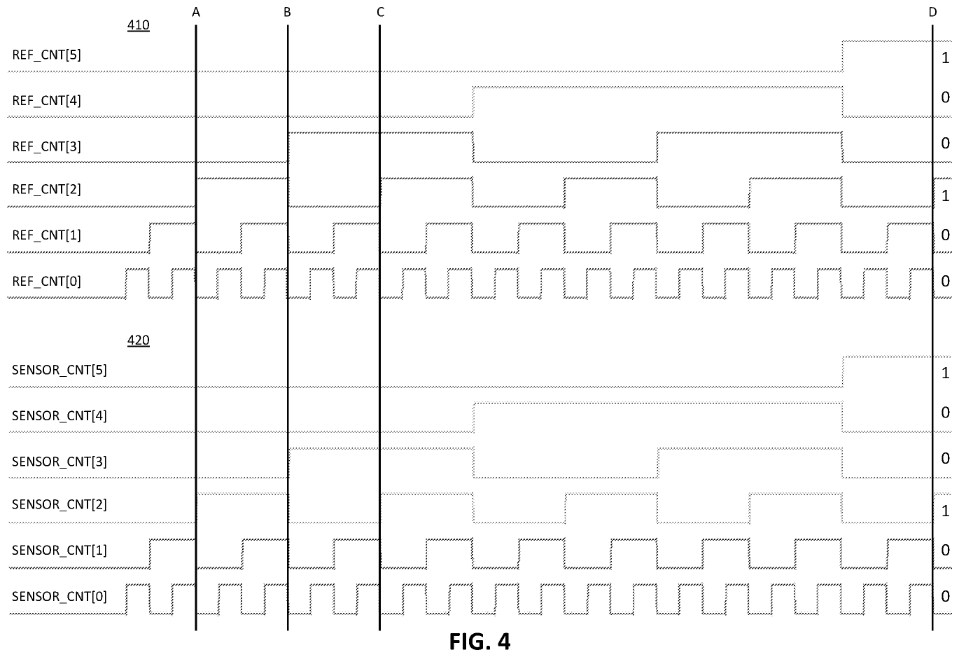

FIG. 4 is a representation of an example of a comparison between the reference circuit and the sensor circuit for a non-aged circuit. Diagram 410 represents a signal count for a reference circuit. Diagram 420 represents a parallel signal count for a sensor circuit. The vertical lines illustrate the comparison of the two counts.

Diagram 410 illustrates the function for the first six bits of the reference count (REF_CNT), specifically illustrating signal lines for REF_CNT [0:5]. Diagram 420 illustrates the function for the first six bits of the sensor count (SENSOR_CNT), specifically illustrating signal lines for SENSOR_CNT [0:5]. The diagrams only illustrate the difference in transition edges for the three least significant bits.

As illustrated, at time A, time B, and time C are all aligned between the reference count and the sensor count. At time D, the output count for the two counters is the same, which is ‘100100’ for the reference circuit and ‘100100’ for the sensor circuit. Diagram 410 and diagram 420 illustrate a condition when the DUT is new enough that there has not been significant aging of the monitored circuitry.

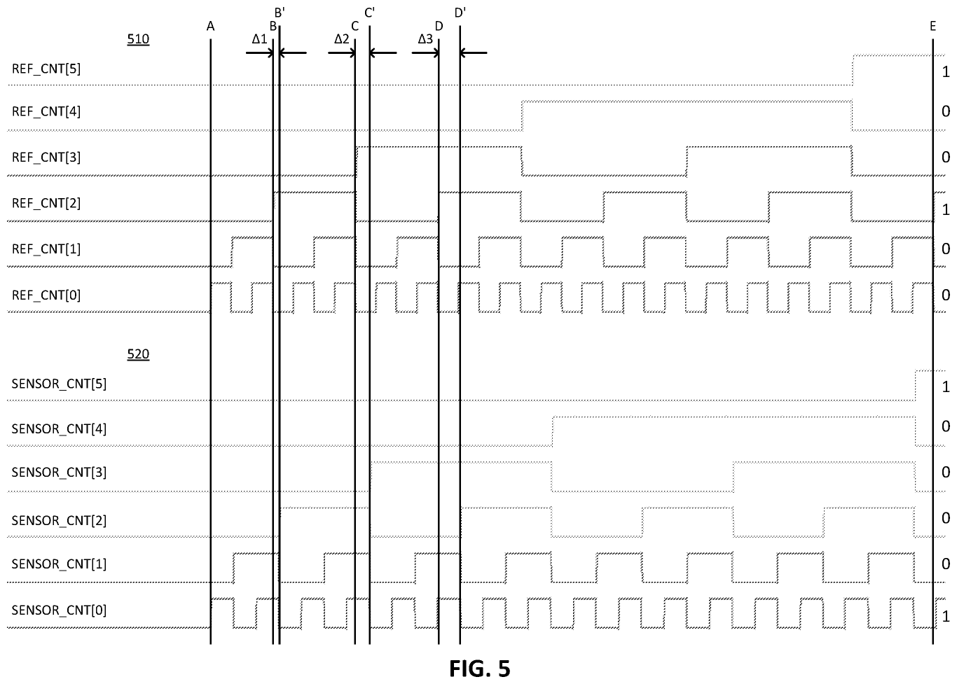

FIG. 5 is a representation of an example of a comparison between the reference circuit and the sensor circuit for an aged circuit. Diagram 510 represents a signal count for a reference circuit. Diagram 520 represents a parallel signal count for a sensor circuit. The vertical lines illustrate the comparison of the two counts.

Diagram 510 illustrates the function for the first six bits of the reference count (REF_CNT), specifically illustrating signal lines for REF_CNT [0:5]. Diagram 520 illustrates the function for the first six bits of the sensor count (SENSOR_CNT), specifically illustrating signal lines for SENSOR_CNT [0:5]. The diagrams only illustrate the difference in transition edges for the three least significant bits.

Diagram 510 and diagram 520 represent a condition of aging for the DUT circuitry. Time A illustrates that both counters initiate at the same time. As illustrated, REF_CNT [0] transitions at time B, while SENSOR_CNT [0] transitions at time B′, illustrating a delay of A1. Similarly, REF_CNT [1] transitions at time C, while SENSOR_CNT [1] transitions at time C′, with a delay of 42, and REF_CNT [2] transitions at time D, while SENSOR_CNT [2] transitions at time D′, with a delay of A3.

The deltas illustrated (41, 42, 43) show the difference in clock edges simply to indicate that the ROs have different timings. In one example, the difference or delta that matters for the aging circuit is simply the difference in the final count between the reference circuit and the sensor circuit. The same concept of the deltas between clock edges and the overall delta of the counter applies to the other timing diagrams that follow.

At time E, the system output count of the reference circuit is ‘100100’ and the output count of the sensor circuit is ‘100001’ because it is counting slower. Diagram 510 and diagram 520 illustrate a condition when the DUT has experienced aging degradation, where there is a difference of 3 in the counters.

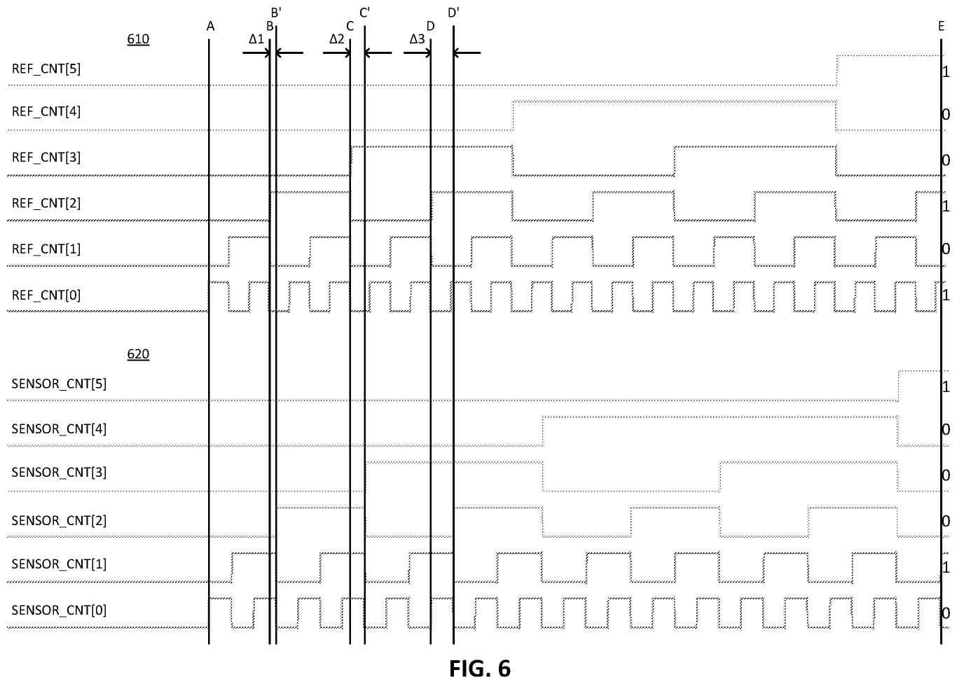

FIG. 6 is a representation of an example of a comparison between the reference circuit and the sensor circuit for temperature changes. Diagram 610 represents a signal count for a reference circuit. Diagram 620 represents a parallel signal count for a sensor circuit. The vertical lines illustrate the comparison of the two counts.

Diagram 610 illustrates the function for the first six bits of the reference count (REF_CNT), specifically illustrating signal lines for REF_CNT [0:5]. Diagram 620 illustrates the function for the first six bits of the sensor count (SENSOR_CNT), specifically illustrating signal lines for SENSOR_CNT [0:5]. The diagrams only illustrate the difference in transition edges for the three least significant bits.

Diagram 610 and diagram 620 represent a condition where the system accounts for temperature differences in aging monitoring for the DUT circuitry with differential monitoring. Time A illustrates that both counters initiate at the same time. As illustrated, REF_CNT [0] transitions at time B, while SENSOR_CNT [0] transitions at time B′, illustrating a delay of A1. Similarly, REF_CNT [1] transitions at time C, while SENSOR_CNT [1] transitions at time C′, with a delay of 42, and REF_CNT [2] transitions at time D, while SENSOR_CNT [2] transitions at time D′, with a delay of 43.

At time E, the system output count of the reference circuit is ‘100101’ and the output count of the sensor circuit is ‘100010’ because it is counting slower. Diagram 610 and diagram 620 illustrate how the aging monitor output can be temperature dependent. Diagram 610 and diagram 620 should be evaluated in light of diagram 510 and diagram 520, which show only the aging effect. It will be observed that instead of the sensor count being ‘100001’ as in diagram 510, the count in diagram 610 is ‘100010’, which is one count higher.

Depending on the temperature, the aging monitor value itself can vary because of device characteristics. To evaluate the degradation due to aging rather than temperature, the system would need to decouple the temperature effect as much as possible from the sensor values. However, the temperature calibration process is expensive and requires additional hardware overhead (e.g., heater, memory, calculation unit).

If the system relied only on a single sensor count as a single sensor, the sensor counter value of ‘100010’ would not give an accurate picture of the aging, as the frequency degradation would appear to be only 2 (the ‘100100’ of the fresh circuit minus the ‘100010’ of diagram 620), which is not correct. With differential monitoring with the reference circuit, diagram 610 has also changed, going up from ‘100100’ to ‘100101’, maintaining a correct difference of 3 between the reference count and the sensor count.

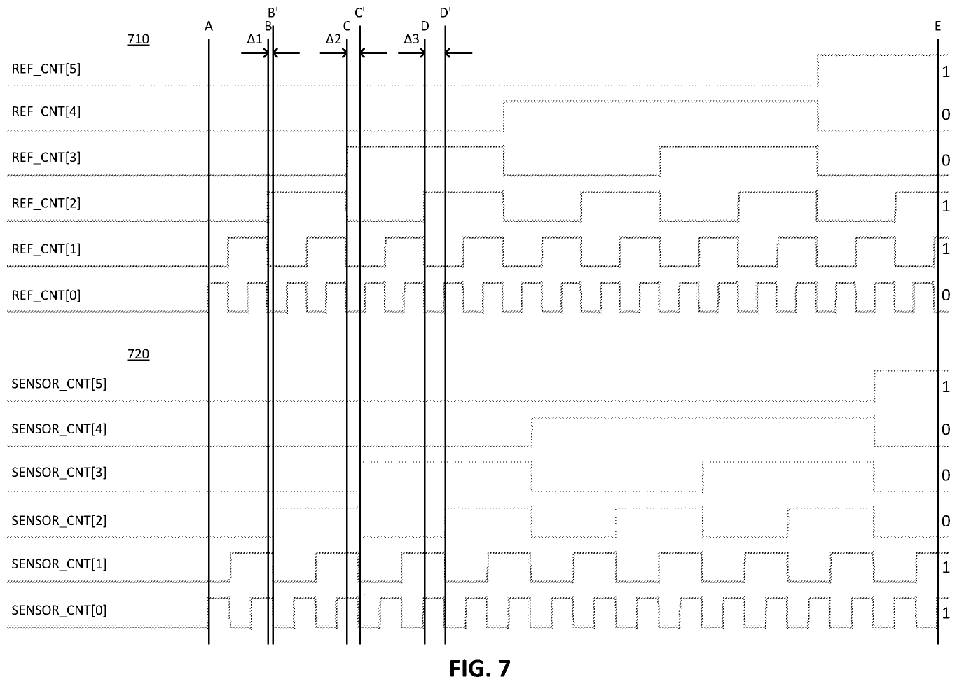

FIG. 7 is a representation of an example of a comparison between the reference circuit and the sensor circuit for voltage supply changes. Diagram 710 represents a signal count for a reference circuit. Diagram 720 represents a parallel signal count for a sensor circuit. The vertical lines illustrate the comparison of the two counts.

Diagram 710 illustrates the function for the first six bits of the reference count (REF_CNT), specifically illustrating signal lines for REF_CNT [0:5]. Diagram 720 illustrates the function for the first six bits of the sensor count (SENSOR_CNT), specifically illustrating signal lines for SENSOR_CNT [0:5]. The diagrams only illustrate the difference in transition edges for the three least significant bits.

Diagram 710 and diagram 720 represent a condition where the system accounts for voltage noise differences in aging monitoring for the DUT circuitry with differential monitoring. Time A illustrates that both counters initiate at the same time. As illustrated, REF_CNT [0] transitions at time B, while SENSOR_CNT [0] transitions at time B′, illustrating a delay of A1. Similarly, REF_CNT [1] transitions at time C, while SENSOR_CNT [1] transitions at time C′, with a delay of A2, and REF_CNT [2] transitions at time D, while SENSOR_CNT [2] transitions at time D′, with a delay of A3.

At time E, the system output count of the reference circuit is ‘100110’ and the output count of the sensor circuit is ‘100011’ because it is counting slower. Diagram 710 and diagram 720 illustrate how the aging monitor output can be dependent on voltage noise. Diagram 710 and diagram 720 should be evaluated in light of diagram 510 and diagram 520, which show only the aging effect. It will be observed that instead of the sensor count being ‘100001’ as in diagram 510, the count in diagram 710 is ‘100010’, which is one count higher.

With voltage noise variations, as with temperature, the aging circuit could end up with a misleading output. The correct values can be maintained with differential monitoring. Consider a voltage variation of 30 mV in the system of the DUT. If the system relied only on a single sensor count as a single sensor, the sensor counter value of ‘100011’ would not give an accurate picture of the aging, as the frequency degradation would appear to be only 1 (the ‘100100’ of the fresh circuit minus the ‘100011’ of diagram 720), which is not correct. With differential monitoring with the reference circuit, diagram 710 has also changed, going up from ‘100100’ to ‘100110’, maintaining a correct difference of 3 between the reference count and the sensor count.

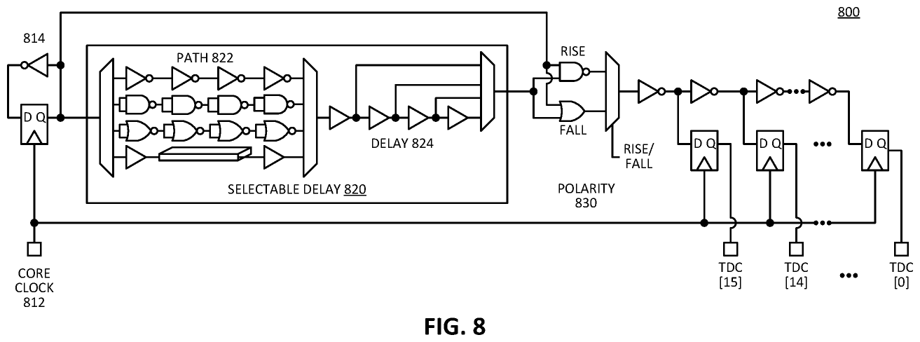

FIG. 8 is a circuit diagram of an example of a tunable replica circuit. System 800 illustrates a TRC (tunable replica circuit) that can enable a system to adapt to adapt to voltage, temperature, and aging variations with dynamic voltage and dynamic frequency in response to detection of aging errors. A TRC such as system 800 can optionally be used in conjunction with an aging monitor as described herein.

System 800 includes selectable delay 820, which enables the system to dynamically select delay based on detected aging for a DUT. Selectable delay 820 can include path 822 to select inverter delay, OR delay, AND delay, or other delay as a selectable path type. Delay 824 represents a tunable delay.

The output of selectable delay 820 can provide an input to polarity 830, which represents a circuit to select the type of delay to add, whether the rising edge (RISE) or the falling edge (FALL). Polarity 830 can include a multiplexed output to select between the rising and falling edge.

The output can be ANDed for the rising edge with the output of the latch at 814 and ORed with the latch output. The latch output can be fed back to the input to count up. The latch can enable through signal 812, which represents a core clock signal. The core clock signal can also enable the tunable delay count latches.

System 800 illustrates a tunable delay count of TDC [15:0]. The delay count can be any number of bits selected for the system, where the sixteen bits illustrated is merely one example. It will be understood that system 800 can be used in conjunction with a differential aging monitor implemented in accordance with any example herein. The TDC circuit illustrated can provide a count to enable dynamic voltage or dynamic voltage for a system to adapt to the aging.

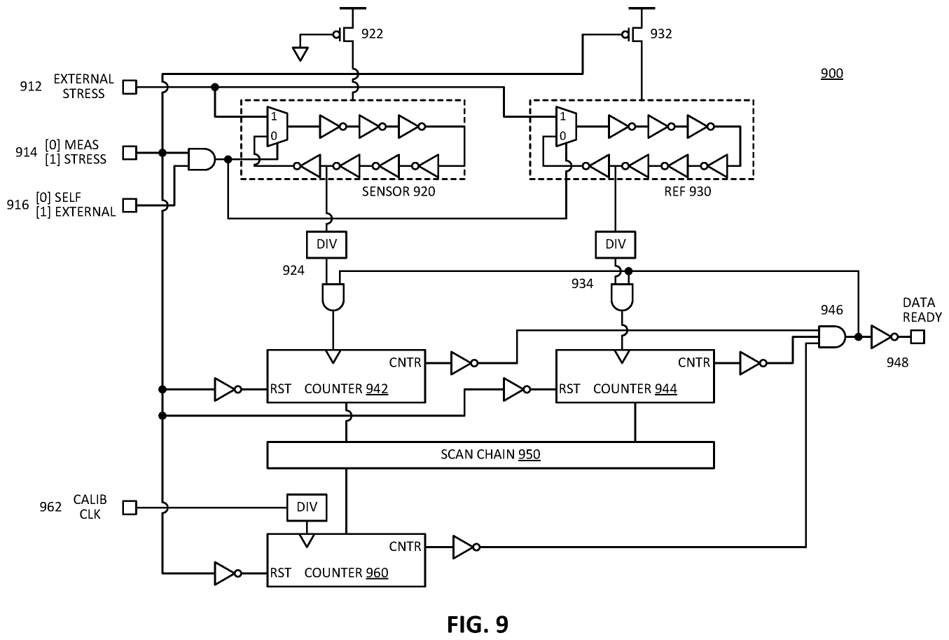

FIG. 9 is a circuit diagram of an example of a clock-less and calibration-less aging monitor with frequency measurement. System 900 illustrates a differential aging monitor in accordance with any example herein. The aging monitor circuitry of system 900 is the same as what is described with respect to FIG. 2. For completeness, the descriptions are repeated below with respect to system 900.

In addition to the aging monitor circuitry, in one example, system 900 includes optional circuitry for frequency measurement. In one example, the frequency monitor circuit detects a frequency change based on circuit aging. System 200 provides a difference between the reference RO and the sensor RO that is subject to aging, and does not provide the absolute frequency value. System 900 includes counter 960, where a reference clock with known frequency is fed to the counter. Signal 962 represents a calibration clock (CALIB CLK) signal as the known frequency input for counter 960. In one example, signal 962 can be input to counter 960 through a divider, to match the division provided for the inputs to counter 942 and counter 944.

Counter 960 can also be reset (RST) through the measurement mode signal. In one example, once counter 960 reaches a maximum count (CNTR), it can stop counter 942 and counter 944. Counter 960 can stop the other counters from counting by providing the CNTR output to be ANDed with device 946 with the count control signals from the other counters. By knowing the number of bits in each counter and the reference clock frequency (CALIB CLK), the system can calculate the exact frequency degradation of the sensor RO. As such, system 900 can provide frequency information without a separate TRC circuit.

System 900 represents an aging detection circuit in accordance with an example of an aging monitor of system 100 and system 200. System 900 can be implemented as a monitoring circuit for any component that is to be monitored for aging. Thus, system 900 represents circuitry that can be incorporated into a larger system. The larger system can have multiple instances of system 900.

System 900 represents a clockless and calibration-less aging monitor. As illustrated, system 900 includes two ROs (ring oscillators), each with its own power gate. The separate power gates for the separate ROs enable system 900 to have a reference RO with a power gate that is selectively enabled to allow for selective measurement operation, and a power gate that is always on for a sensor RO.

While system 900 specifically illustrates ring oscillators, in one example, the sensor circuit and the reference circuit can be implemented with different circuits that can generate a differential signal for comparison. System 900 illustrates two counters, one for each RO, with simple logic to interface the counters with the sensing circuitry.

In one example, system 900 includes sensor 920, which represents the sensor portion of the aging monitor. Sensor 920 is power gated by device 922, which is illustrated to be tied to an always-on position. Thus, when the larger system is operational, sensor 920 will be operational.

In one example, system 900 includes reference (REF) 930, which represents the reference portion of the aging monitor. Reference 930 is power gated by device 932, which is controlled by a control signal. In one example, a controller (not specifically illustrated) of the larger system generates the control signal to trigger aging measurement.

System 900 keeps reference 930 fresh during the lifetime of the product by applying power gating through device 932, meaning reference RO power is turned off when not in use for measurement, which means the circuit will not age at the same rate as the operational circuitry. The measurement can be controlled during a measurement mode. In one example, a control algorithm selectively writes a configuration register to start and stop aging measurement. In one example, the control algorithm generates a control signal from an I/O (input/output) circuit to control the power gate.

In one example, sensor 920 feeds an output signal to divider 924. In one example, reference 930 feeds an output signal to divider 934. The dividers can divide the RO frequency before feeding counters. In one example, the output of divider 924 is ANDed with a feedback signal to feed into counter 942. Likewise, in one example, output of divider 934 is ANDed with the feedback signal to feed into counter 944.

Counter 942 and counter 944 can be N-bit counters. To ensure that the measurement is made based on useful measurements, counter 942 and counter 944 can include reset (RST) inputs triggered by the measurement mode control signal. Thus, when the system begins measurement mode, the counters are reset and will count in parallel from the initial count.

Counter 942 can be referred to as a sensor counter, since it counts the signal from the sensor circuit, which can be referred to as a sensor count. Counter 944 can be referred to as a reference counter, since it counts the signal from the reference circuit, which can be referred to as a reference count. In one example, the counter (CNTR) outputs of counter 942 and counter 944 can be ANDed with device 946 and fed back into the signal with the respective dividers. The counter output can be a pre-selected count value for each counter.

Thus, in one example, counter 942 can be configured to stop counting when it reaches a count value in the sensor DUT (device under test). In one example, counter 944 will stop counting at a pre-selected counter value in the reference DUT. By stopping the counting, system 900 can hold the count values without overflow. The output at device 948 can provide a data ready signal to the external controller that makes use of the aging monitoring data.

Counter 942 and counter 944 can output their counts to scan chain 950, which can couple to external control circuitry (not illustrated) to perform operations in response to the count output. In one example, scan chain 950 includes comparator circuitry to compare the count from the sensor portion with the count from the reference portion to determine how the operational circuitry is aging. In one example, scan chain 950 is connected to the counter enable.

System 900 represents multiple control signal inputs as examples. Other control signal inputs can be used. Signal 912 represents an externa stress signal, which can trigger the ROs to run at the system clock frequency. Thus, system 900 represents an aging monitor that can run without a system clock signal, but can optionally run the circuits at the clock frequency. System 900 does not require complicated calibration in the product. In one example, sensor 920 and reference 930 are ROs that can run in self-oscillation mode or can also be stressed at the clock frequency.

Signal 914 represents a measurement mode signal. In one example, when the signal is low [0], it is can trigger measurement mode, and when the signal is high [1], it can switch to a stress mode. Thus, in one example, system 900 can be dynamically controlled by an external controller to switch between stress mode and measurement mode. The stress mode can enable sensor 920 to age at the same rate as the operational circuitry. The measurement signal can be a step signal that does not require high precision and timing.

In addition to the external stress signal, in one example, system 900 provides signal 916, which can represent an enable signal for selecting the external stress signal or using the internal frequency. Signal 916 can trigger the internal frequency as the default with low [0] being a Self signal, and high [1] being an External selection.

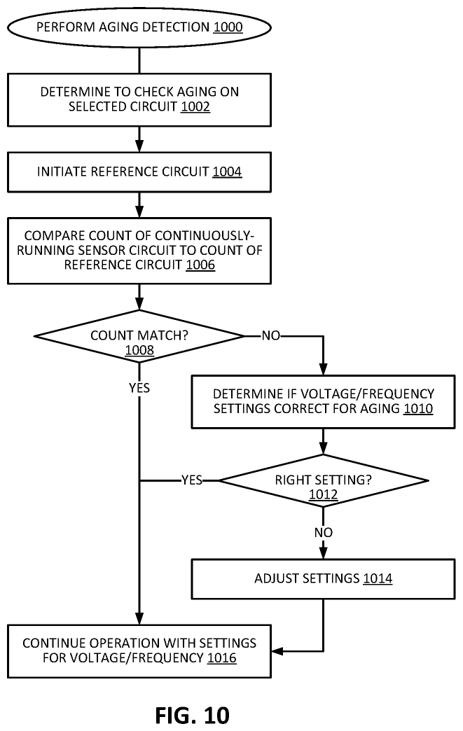

FIG. 10 is a flow diagram of a process for aging detection. Process 1000 represents a process for aging detection with a differential aging monitor in accordance with any example herein. In one example, the system determines to check aging on a selected circuit, at 1002. A controller that manages the aging monitoring can initiate the reference circuit portion of the aging monitor, at 1004. The aging monitor generates a sensor count and a reference count.

In one example, the system compares the count of the continuously running sensor circuit to the count of the reference circuit, at 1006. In one example, the comparison occurs in the controller. In one example, the comparison occurs in the controller.

If the count matches, at 1008 YES branch, the system can continue operation with settings for voltage and/or frequency, at 1016. If the count does not match, at 1008 NO branch, the system can determine if the voltage and/or the frequency settings correct for aging, at 1010.

If the settings for the aging are already correct, at 1012 YES branch, the system can continue operation with settings for the voltage/frequency, at 1016. In one example, if the settings are not correct for the voltage or frequency, at 1012 NO branch, the system can adjust the settings, at 1014. The system can then continue operation with the settings for the voltage/frequency, at 1016.

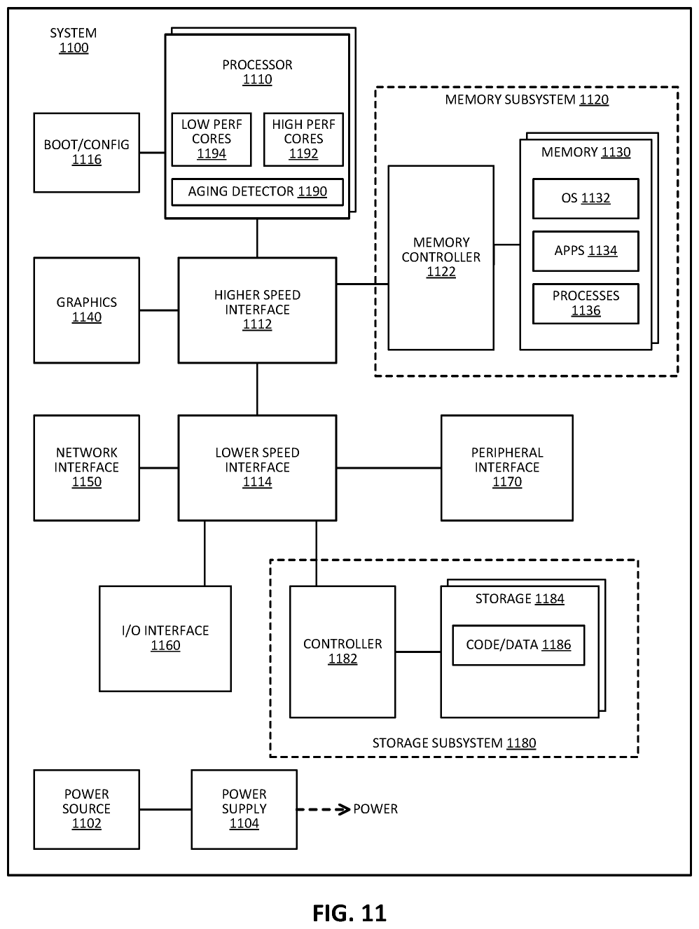

FIG. 11 is a block diagram of an example of a computing system in which aging detection can be implemented. System 1100 represents a computing device in accordance with any example herein, and can be a laptop computer, a desktop computer, a tablet computer, a server, a gaming or entertainment control system, embedded computing device, or other electronic device.

System 1100 represents a system with aging monitoring in accordance with an example of system 100, system 200, or system 900. In one example, processor 1110 includes low performance (PERF) cores 1194 and high performance (PERF) cores 1192. System 1100 includes aging detector 1190, which represents an example of an aging monitor in accordance with any example herein. In one example, aging detector 1190 only monitors the aging of higher performance cores 1192. System 1100 does not show aging detectors on circuits other than processor 1110, however, it will be understood that system 1100 can implement aging detectors on any circuit where aging is to be monitored.

System 1100 includes processor 1110 can include any type of microprocessor, central processing unit (CPU), graphics processing unit (GPU), processing core, or other processing hardware, or a combination, to provide processing or execution of instructions for system 1100. Processor 1110 can be a host processor device. Processor 1110 controls the overall operation of system 1100, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1100 includes boot/config 1116, which represents storage to store boot code (e.g., basic input/output system (BIOS)), configuration settings, security hardware (e.g., trusted platform module (TPM)), or other system level hardware that operates outside of a host OS. Boot/config 1116 can include a nonvolatile storage device, such as read-only memory (ROM), flash memory, or other memory devices.

In one example, system 1100 includes interface 1112 coupled to processor 1110, which can represent a higher speed interface or a high throughput interface for system components that need higher bandwidth connections, such as memory subsystem 1120 or graphics interface components 1140. Interface 1112 represents an interface circuit, which can be a standalone component or integrated onto a processor die. Interface 1112 can be integrated as a circuit onto the processor die or integrated as a component on a system on a chip. Where present, graphics interface 1140 interfaces to graphics components for providing a visual display to a user of system 1100. Graphics interface 1140 can be a standalone component or integrated onto the processor die or system on a chip. In one example, graphics interface 1140 can drive a high definition (HD) display or ultra high definition (UHD) display that provides an output to a user. In one example, the display can include a touchscreen display. In one example, graphics interface 1140 generates a display based on data stored in memory 1130 or based on operations executed by processor 1110 or both.

Memory subsystem 1120 represents the main memory of system 1100, and provides storage for code to be executed by processor 1110, or data values to be used in executing a routine. Memory subsystem 1120 can include one or more varieties of random-access memory (RAM) such as DRAM, 3DXP (three-dimensional crosspoint), or other memory devices, or a combination of such devices. Memory 1130 stores and hosts, among other things, operating system (OS) 1132 to provide a software platform for execution of instructions in system 1100. Additionally, applications 1134 can execute on the software platform of OS 1132 from memory 1130. Applications 1134 represent programs that have their own operational logic to perform execution of one or more functions. Processes 1136 represent agents or routines that provide auxiliary functions to OS 1132 or one or more applications 1134 or a combination. OS 1132, applications 1134, and processes 1136 provide software logic to provide functions for system 1100. In one example, memory subsystem 1120 includes memory controller 1122, which is a memory controller to generate and issue commands to memory 1130. It will be understood that memory controller 1122 could be a physical part of processor 1110 or a physical part of interface 1112. For example, memory controller 1122 can be an integrated memory controller, integrated onto a circuit with processor 1110, such as integrated onto the processor die or a system on a chip.

While not specifically illustrated, it will be understood that system 1100 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1100 includes interface 1114, which can be coupled to interface 1112. Interface 1114 can be a lower speed interface than interface 1112. In one example, interface 1114 represents an interface circuit, which can include standalone components and integrated circuitry. In one example, multiple user interface components or peripheral components, or both, couple to interface 1114. Network interface 1150 provides system 1100 the ability to communicate with remote devices (e.g., servers or other computing devices) over one or more networks. Network interface 1150 can include an Ethernet adapter, wireless interconnection components, cellular network interconnection components, USB (universal serial bus), or other wired or wireless standards-based or proprietary network interface circuit. Network interface 1150 can exchange data over a network connection with a remote device, which can include sending data stored in memory or receiving data to be stored in memory.

In one example, system 1100 includes one or more input/output (I/O) interface(s) 1160. I/O interface 1160 can include one or more interface components through which a user interacts with system 1100 (e.g., audio, alphanumeric, tactile/touch, or other interfacing). Peripheral interface 1170 can include any hardware interface not specifically mentioned above. Peripherals refer generally to devices that connect dependently to system 1100. A dependent connection is one where system 1100 provides the software platform or hardware platform or both on which operation executes, and with which a user interacts.

In one example, system 1100 includes storage subsystem 1180 to store data in a nonvolatile manner. In one example, in certain system implementations, at least certain components of storage 1180 can overlap with components of memory subsystem 1120. Storage subsystem 1180 includes storage device(s) 1184, which can be or include any conventional medium for storing large amounts of data in a nonvolatile manner, such as one or more magnetic, solid state, NAND, 3DXP, or optical based disks, or a combination. Storage 1184 holds code or instructions and data 1186 in a persistent state (i.e., the value is retained despite interruption of power to system 1100). Storage 1184 can be generically considered to be a “memory,” although memory 1130 is typically the executing or operating memory to provide instructions to processor 1110. Whereas storage 1184 is nonvolatile, memory 1130 can include volatile memory (i.e., the value or state of the data is indeterminate if power is interrupted to system 1100). In one example, storage subsystem 1180 includes controller 1182 to interface with storage 1184. In one example controller 1182 is a physical part of interface 1114 or processor 1110, or can include circuits or logic in both processor 1110 and interface 1114.

Power source 1102 provides power to the components of system 1100. More specifically, power source 1102 typically interfaces to one or multiple power supplies 1104 in system 1100 to provide power to the components of system 1100. In one example, power supply 1104 includes an AC to DC (alternating current to direct current) adapter to plug into a wall outlet. Such AC power can be renewable energy (e.g., solar power) power source 1102. In one example, power source 1102 includes a DC power source, such as an external AC to DC converter. In one example, power source 1102 or power supply 1104 includes wireless charging hardware to charge via proximity to a charging field. In one example, power source 1102 can include an internal battery or fuel cell source.

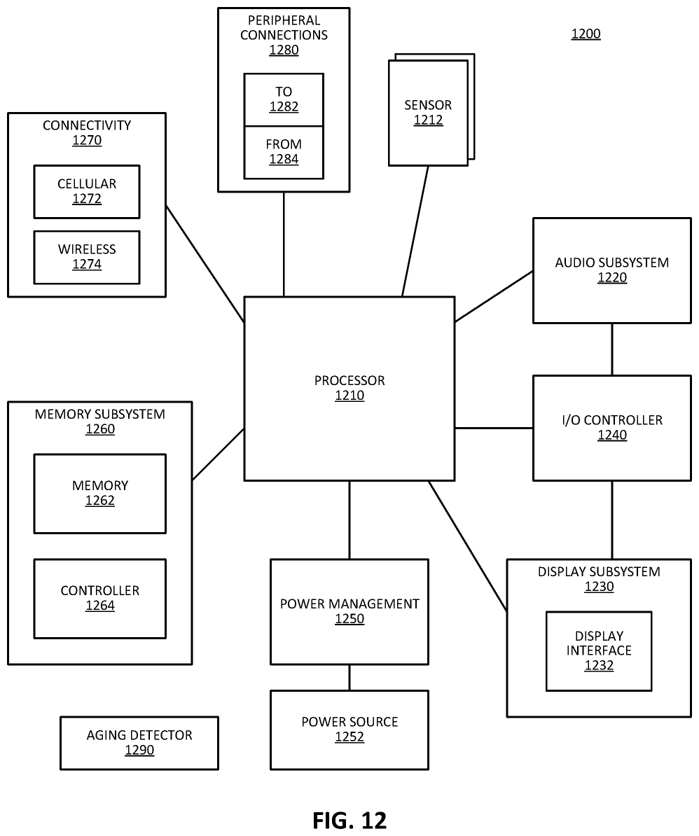

FIG. 12 is a block diagram of an example of a compact device in which aging detection can be implemented. System 1200 represents a compact computing device, such as a computing tablet, a mobile phone or smartphone, wearable computing device, or other mobile device, or an embedded computing device. It will be understood that certain of the components are shown generally, and not all components of such a device are shown in system 1200.

System 1200 represents a system with aging monitoring in accordance with an example of system 100, system 200, or system 900. In one example, system 1200 includes aging detector 1290, which represents an example of an aging monitor in accordance with any example herein. System 1200 does not specifically show where aging detector 1290 is implemented. Aging detector 1290 represents one or more aging monitors that can be implemented in any circuit where aging is to be monitored.

System 1200 includes processor 1210, which performs the primary processing operations of system 1200. Processor 1210 can be a host processor device. Processor 1210 can include one or more physical devices, such as microprocessors, application processors, microcontrollers, programmable logic devices, or other processing means. The processing operations performed by processor 1210 include the execution of an operating platform or operating system on which applications and device functions are executed. The processing operations include operations related to I/O (input/output) with a human user or with other devices, operations related to power management, operations related to connecting system 1200 to another device, or a combination. The processing operations can also include operations related to audio I/O, display I/O, or other interfacing, or a combination. Processor 1210 can execute data stored in memory. Processor 1210 can write or edit data stored in memory.

In one example, system 1200 includes one or more sensors 1212. Sensors 1212 represent embedded sensors or interfaces to external sensors, or a combination. Sensors 1212 enable system 1200 to monitor or detect one or more conditions of an environment or a device in which system 1200 is implemented. Sensors 1212 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1212 can also include sensors for biometric systems such as fingerprint recognition systems, face detection or recognition systems, or other systems that detect or recognize user features. Sensors 1212 should be understood broadly, and not limiting on the many different types of sensors that could be implemented with system 1200. In one example, one or more sensors 1212 couples to processor 1210 via a frontend circuit integrated with processor 1210. In one example, one or more sensors 1212 couples to processor 1210 via another component of system 1200.

In one example, system 1200 includes audio subsystem 1220, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 1200, or connected to system 1200. In one example, a user interacts with system 1200 by providing audio commands that are received and processed by processor 1210.

Display subsystem 1230 represents hardware (e.g., display devices) and software components (e.g., drivers) that provide a visual display for presentation to a user. In one example, the display includes tactile components or touchscreen elements for a user to interact with the computing device. Display subsystem 1230 includes display interface 1232, which includes the particular screen or hardware device used to provide a display to a user. In one example, display interface 1232 includes logic separate from processor 1210 (such as a graphics processor) to perform at least some processing related to the display. In one example, display subsystem 1230 includes a touchscreen device that provides both output and input to a user. In one example, display subsystem 1230 includes a high definition (HD) or ultra-high definition (UHD) display that provides an output to a user. In one example, display subsystem includes or drives a touchscreen display. In one example, display subsystem 1230 generates display information based on data stored in memory or based on operations executed by processor 1210 or both.

I/O controller 1240 represents hardware devices and software components related to interaction with a user. I/O controller 1240 can operate to manage hardware that is part of audio subsystem 1220, or display subsystem 1230, or both. Additionally, I/O controller 1240 illustrates a connection point for additional devices that connect to system 1200 through which a user might interact with the system. For example, devices that can be attached to system 1200 might include microphone devices, speaker or stereo systems, video systems or other display device, keyboard or keypad devices, buttons/switches, or other I/O devices for use with specific applications such as card readers or other devices.

As mentioned above, I/O controller 1240 can interact with audio subsystem 1220 or display subsystem 1230 or both. For example, input through a microphone or other audio device can provide input or commands for one or more applications or functions of system 1200. Additionally, audio output can be provided instead of or in addition to display output. In another example, if display subsystem includes a touchscreen, the display device also acts as an input device, which can be at least partially managed by I/O controller 1240. There can also be additional buttons or switches on system 1200 to provide I/O functions managed by I/O controller 1240.

In one example, I/O controller 1240 manages devices such as accelerometers, cameras, light sensors or other environmental sensors, gyroscopes, global positioning system (GPS), or other hardware that can be included in system 1200, or sensors 1212. The input can be part of direct user interaction, as well as providing environmental input to the system to influence its operations (such as filtering for noise, adjusting displays for brightness detection, applying a flash for a camera, or other features).

In one example, system 1200 includes power management 1250 that manages battery power usage, charging of the battery, and features related to power saving operation. Power management 1250 manages power from power source 1252, which provides power to the components of system 1200. In one example, power source 1252 includes an AC to DC (alternating current to direct current) adapter to plug into a wall outlet. Such AC power can be renewable energy (e.g., solar power, motion based power). In one example, power source 1252 includes only DC power, which can be provided by a DC power source, such as an external AC to DC converter. In one example, power source 1252 includes wireless charging hardware to charge via proximity to a charging field. In one example, power source 1252 can include an internal battery or fuel cell source.

Memory subsystem 1260 includes memory device(s) 1262 for storing information in system 1200. Memory subsystem 1260 can include nonvolatile (state does not change if power to the memory device is interrupted) or volatile (state is indeterminate if power to the memory device is interrupted) memory devices, or a combination. Memory 1260 can store application data, user data, music, photos, documents, or other data, as well as system data (whether long-term or temporary) related to the execution of the applications and functions of system 1200. In one example, memory subsystem 1260 includes memory controller 1264 (which could also be considered part of the control of system 1200, and could potentially be considered part of processor 1210). Memory controller 1264 includes a scheduler to generate and issue commands to control access to memory device 1262.

Connectivity 1270 includes hardware devices (e.g., wireless or wired connectors and communication hardware, or a combination of wired and wireless hardware) and software components (e.g., drivers, protocol stacks) to enable system 1200 to communicate with external devices. The external device could be separate devices, such as other computing devices, wireless access points or base stations, as well as peripherals such as headsets, printers, or other devices. In one example, system 1200 exchanges data with an external device for storage in memory or for display on a display device. The exchanged data can include data to be stored in memory, or data already stored in memory, to read, write, or edit data.

Connectivity 1270 can include multiple different types of connectivity. To generalize, system 1200 is illustrated with cellular connectivity 1272 and wireless connectivity 1274. Cellular connectivity 1272 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 5G, or other cellular service standards. Wireless connectivity 1274 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1280 include hardware interfaces and connectors, as well as software components (e.g., drivers, protocol stacks) to make peripheral connections. It will be understood that system 1200 could both be a peripheral device (“to” 1282) to other computing devices, as well as have peripheral devices (“from” 1284) connected to it. System 1200 commonly has a “docking” connector to connect to other computing devices for purposes such as managing (e.g., downloading, uploading, changing, synchronizing) content on system 1200. Additionally, a docking connector can allow system 1200 to connect to certain peripherals that allow system 1200 to control content output, for example, to audiovisual or other systems.

In addition to a proprietary docking connector or other proprietary connection hardware, system 1200 can make peripheral connections 1280 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

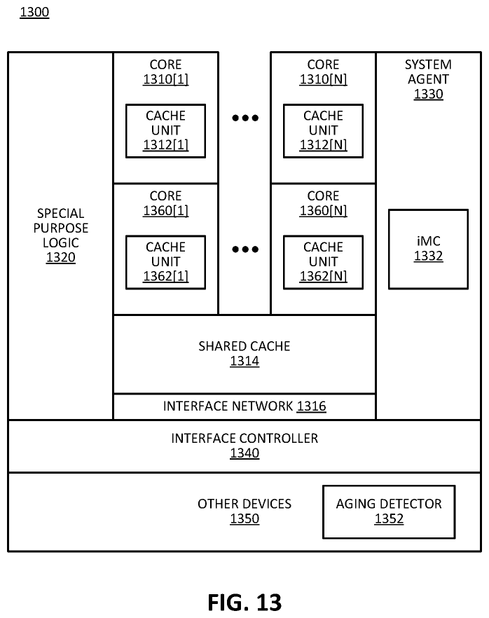

FIG. 13 is a block diagram of an example of an SOC in which aging detection can be implemented. System 1300 illustrates an example of a processor or an SOC that has one or more processor cores. System 1300 can be implemented as one semiconductor chip or multiple semiconductor chips. In one example, system 1300 includes aging detector 1352, which represents an example of an aging monitor in accordance with any example herein.

System 1300 includes one or more cores, represented by core 1310 [1], . . . core 1310 [N], collectively cores 1310. Cores 1310 can represent high performance cores for system 1300. System 1300 includes one or more low performance cores, represented by core 1360 [1], . . . core 1360 [N], collectively cores 1360. System 1300 includes system agent 1330, which represents system agent unit circuitry to manage memory access. In one example, system agent 1330 includes iMC (integrated memory controller) 1332. In one example, system 1300 includes one or more interface controller 1340, which can represent interface controller unit circuitry. System 1300 can include special purpose logic 1320.

Different implementations of system 1300 can include: a CPU with special purpose logic 1320 being integrated graphics, scientific throughput logic (which may include one or more cores), and cores 1310 can be one or more general purpose cores (e.g., general purpose in-order cores, general purpose out-of-order cores, or a combination of the two); a coprocessor with cores 1310 being a large number of special purpose cores intended primarily for graphics or scientific computations and throughput; or a coprocessor with cores 1310 being a large number of general purpose in-order cores. Thus, system 1300 can include or can be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or other processor system. The processor can be implemented on one or more chips, such as multiple chiplets connected through a chiplet communication network. The processor can be a part of or be implemented on one or more substrates using any of a number of process technologies, such as, for example, CMOS (complementary metal oxide semiconductor), BiCMOS (bipolar CMOS), PMOS (P-type metal oxide semiconductor), or NMOS (N-type metal oxide semiconductor).

In one example, system 1300 has a memory hierarchy including one or more levels of cache illustrated by cache unit 1312 [1], . . . cache unit 1312 [N], collectively cache units 1312. Cache units 1312 can be circuitry on cores 1310. In one example, the memory hierarchy includes one or more levels of cache illustrated by cache unit 1362 [1], . . . cache unit 1362 [N], collectively cache units 1362. Cache units 1362 can be circuitry on cores 1360. The memory hierarchy can include the cache and external memory (not shown) coupled to iMC 1332. In one example, system 1300 has mid-level caches, such as level 2 (L2), level 3 (L3), level 4 (L4), or other levels of cache, such as a last level cache (LLC), or combinations of cache levels.

In one example, system 1300 includes interface network circuitry 1316, which can be, for example, a ring interconnect, which interfaces special purpose logic 1320 (e.g., integrated graphics logic), shared cache 1314, and system agent 1330. Alternative examples can apply any number of techniques for interfacing such units. In one example, coherency is maintained between one or more of shared cache 1314 and cores 1310. In one example, interface controller 1340 couples cores 1310 to one or more other devices 1350 such as I/O (input/output) devices, storage, one or more communication devices (e.g., wireless networking, wired networking, etc.), and so forth.

In one example, one or more cores 1310 are capable of multi-threading. System agent 1330 includes components for coordinating and operating cores 1310 related to multithreading. System agent 1330 can include, for example, PCU (power control unit) circuitry or display unit circuitry (not shown). The PCU can be or include logic and components needed for regulating the power state of cores 1310 or of special purpose logic 1320 (e.g., integrated graphics logic), or both. The display unit circuitry can drive one or more externally connected displays.

Cores 1310 can be homogenous in terms of ISA (instruction set architecture). Alternatively, cores 1310 can be heterogeneous in terms of ISA, where a subset of cores 1310 can execute an ISA, while other cores can execute only a subset of that ISA or another ISA.

In general with respect to the descriptions herein, in one aspect, an apparatus includes: an aging detection circuit including: a sensor count circuit that runs constantly, the sensor count circuit having a sensor counter; a reference count circuit that is off unless enabled for a measurement mode, the reference count circuit having a reference counter; and circuitry coupled to selectively enable the measurement mode, wherein, in the measurement mode the sensor counter and the reference counter generate counts based on their respective count circuits, to determine circuit aging based on a difference between the sensor counter and the reference counter.

In accordance with one example of the apparatus, the sensor count circuit comprises a sensor ring oscillator (RO) and the sensor counter and wherein the reference count circuit comprises a reference RO and the reference counter. In accordance with any preceding example of the apparatus, in one example, the sensor count circuit is constantly enabled on with a power gating circuit hard coded to an enabled state, and wherein the reference count circuit is enabled selectively by a measurement mode signal. In accordance with any preceding example of the apparatus, in one example, the aging detection circuit comprises a memory aging detection circuit. In accordance with any preceding example of the apparatus, in one example, the aging detection circuit comprises an aging detection circuit for a high performance circuit. In accordance with any preceding example of the apparatus, in one example, the high performance circuit comprises a processor core. In accordance with any preceding example of the apparatus, in one example, for a central processing unit having high performance cores and low performance cores, the aging detection circuit comprises an aging detection circuit only for the high performance core. In accordance with any preceding example of the apparatus, in one example, the aging detection circuit further comprising a frequency monitor circuit to detect a frequency change based on circuit aging. In accordance with any preceding example of the apparatus, in one example, the apparatus includes a tunable replica circuit (TRC) coupled to the aging detection circuit, to adjust a voltage or a frequency in response to the circuit aging.

In general with respect to the descriptions herein, in one aspect, a system includes: a processor device; and an aging detection circuit on a semiconductor chip of the processor device, the aging detection circuit including: a sensor count circuit that runs constantly, the sensor count circuit having a sensor counter; a reference count circuit that is off unless enabled for a measurement mode, the reference count circuit having a reference counter; and circuitry coupled to selectively enable the measurement mode, wherein, in the measurement mode the sensor counter and the reference counter generate counts based on their respective count circuits, to determine circuit aging based on a difference between the sensor counter and the reference counter.

In accordance with one example of the system, the sensor count circuit comprises a sensor ring oscillator (RO) and the sensor counter and wherein the reference count circuit comprises a reference RO and the reference counter. In accordance with any preceding example of the system, in one example, the sensor count circuit is constantly enabled on with a power gating circuit hard coded to an enabled state, and wherein the reference count circuit is enabled selectively by a measurement mode signal. In accordance with any preceding example of the system, in one example, the system includes a memory device, wherein the aging detection circuit comprises a memory aging detection circuit for the memory device. In accordance with any preceding example of the system, in one example, the system includes a peripheral chipset, wherein the aging detection circuit comprises an aging detection circuit for the peripheral chipset. In accordance with any preceding example of the system, in one example, the processor device has multiple processor cores, and wherein the aging detection circuit comprises an aging detection circuit for one of the processor cores. In accordance with any preceding example of the system, in one example, for a central processing unit having high performance cores and low performance cores, the aging detection circuit comprises an aging detection circuit only for a high performance core. In accordance with any preceding example of the system, in one example, the aging detection circuit further comprising a frequency monitor circuit to detect a frequency change based on circuit aging. In accordance with any preceding example of the system, in one example, the system includes a tunable replica circuit (TRC) coupled to the aging detection circuit, to adjust a voltage or a frequency in response to the circuit aging. In accordance with any preceding example of the system, in one example, the processor device comprises a multicore processor. In accordance with any preceding example of the system, in one example, the system includes a display communicatively coupled to the processor device. In accordance with any preceding example of the system, in one example, the system includes a battery to power the system. In accordance with any preceding example of the system, in one example, the system includes a network interface circuit to couple with a remote device over a network connection.

In general with respect to the descriptions herein, in one aspect, a method for detecting aging of a circuit includes: running a sensor count circuit constantly; selectively enabling a reference count circuit for a measurement mode; comparing a sensor count from the sensor count circuit with a reference count to generate a difference; and determining circuit aging based on the difference.

In accordance with one example of the method, running the sensor count circuit comprises running a sensor ring oscillator (RO) and wherein selectively enabling the reference count circuit comprises selectively enabling a reference RO. In accordance with any preceding example of the method, in one example, the sensor circuit is constantly enabled on with a power gating circuit hard coded to an enabled state, and wherein selectively enabling the reference count circuit comprises selectively enabling the reference count circuit with a measurement mode signal. In accordance with any preceding example of the method, in one example, determining circuit aging comprises determining aging of a memory device. In accordance with any preceding example of the method, in one example, determining circuit aging comprises determining aging of a high performance circuit. In accordance with any preceding example of the method, in one example, the high performance circuit comprises a processor core. In accordance with any preceding example of the method, in one example, for a central processing unit having high performance cores and low performance cores, determining circuit aging comprises determining aging of only the high performance cores. In accordance with any preceding example of the method, in one example, the method includes detecting a frequency change based on circuit aging with a frequency monitor circuit. In accordance with any preceding example of the method, in one example, the method includes coupled to the aging detection circuit, to adjusting a voltage or a frequency in response to circuit aging with a tunable replica circuit (TRC).

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
an aging detection circuit including:
a sensor count circuit that runs constantly, the sensor count circuit having a sensor counter;
a reference count circuit that is off unless enabled for a measurement mode, the reference count circuit having a reference counter; and
circuitry coupled to selectively enable the measurement mode, wherein, in the measurement mode the sensor counter and the reference counter generate counts based on their respective count circuits, to determine circuit aging based on a difference between the sensor counter and the reference counter.

2. The apparatus of claim 1, wherein the sensor count circuit comprises a sensor ring oscillator (RO) and the sensor counter and wherein the reference count circuit comprises a reference RO and the reference counter.

3. The apparatus of claim 1, wherein the sensor count circuit is constantly enabled on with a power gating circuit hard coded to an enabled state, and wherein the reference count circuit is enabled selectively by a measurement mode signal.

4. The apparatus of claim 1, wherein the aging detection circuit comprises a memory aging detection circuit.

5. The apparatus of claim 1, wherein the aging detection circuit comprises an aging detection circuit for a high performance circuit.

6. The apparatus of claim 5, wherein the high performance circuit comprises a processor core.

7. The apparatus of claim 6, wherein for a central processing unit having high performance cores and low performance cores, the aging detection circuit comprises an aging detection circuit only for the high performance core.

8. The apparatus of claim 1, wherein the aging detection circuit further comprising a frequency monitor circuit to detect a frequency change based on circuit aging.

9. The apparatus of claim 1, further comprising a tunable replica circuit (TRC) coupled to the aging detection circuit, to adjust a voltage or a frequency in response to the circuit aging.

10. A system comprising:
a processor device; and
an aging detection circuit on a semiconductor chip of the processor device, the aging detection circuit including:
a sensor count circuit that runs constantly, the sensor count circuit having a sensor counter;
a reference count circuit that is off unless enabled for a measurement mode, the reference count circuit having a reference counter; and
circuitry coupled to selectively enable the measurement mode, wherein, in the measurement mode the sensor counter and the reference counter generate counts based on their respective count circuits, to determine circuit aging based on a difference between the sensor counter and the reference counter.

11. The system of claim 10, wherein the sensor count circuit comprises a sensor ring oscillator (RO) and the sensor counter and wherein the reference count circuit comprises a reference RO and the reference counter.

12. The system of claim 10, wherein the sensor count circuit is constantly enabled on with a power gating circuit hard coded to an enabled state, and wherein the reference count circuit is enabled selectively by a measurement mode signal.

13. The system of claim 10, further comprising a memory device, wherein the aging detection circuit comprises a memory aging detection circuit for the memory device.

14. The system of claim 10, further comprising a peripheral chipset, wherein the aging detection circuit comprises an aging detection circuit for the peripheral chipset.

15. The system of claim 10, wherein the processor device has multiple processor cores, and wherein the aging detection circuit comprises an aging detection circuit for one of the processor cores.

16. The system of claim 15, wherein for a central processing unit having high performance cores and low performance cores, the aging detection circuit comprises an aging detection circuit only for a high performance core.

17. The system of claim 10, wherein the aging detection circuit further comprising a frequency monitor circuit to detect a frequency change based on circuit aging.

18. The system of claim 10, further comprising a tunable replica circuit (TRC) coupled to the aging detection circuit, to adjust a voltage or a frequency in response to the circuit aging.

19. The system of claim 10,
wherein the processor device comprises a multicore processor;
further comprising a display communicatively coupled to the processor device;
further comprising a battery to power the system; or
further comprising a network interface circuit to couple with a remote device over a network connection.
